(19) United States
(12) Patent Application Publication
(10) Pub. No.: US 2026/0276935 A1
(43) Pub. Date: Sep. 17, 2026

(54) INTEGRATED OPTICAL FIBER SHUFFLE HARNESS FOR SWITCH AND COMPUTE TRAYS

(71) Applicant: Intel Products IP LLC, Santa Clara, CA (US)

(72) Inventors: Josh COLLIER, Royersford, PA (US); Matthew ADILETTA, Bolton, MA (US); Vered BAR BRACHA, Somerville, MA (US); Juan Eduardo DOMINGUEZ, Gilbert, AZ (US); Donald FAW, Hillsboro, OR (US); Damion SEARLS, Portland, OR (US); Boping XIE, San Ramon, CA (US)

(21) Appl. No.: 19/666,999

(22) Filed: May 4, 2026

(51) Int. Cl. G02B 6/44; G02B 6/42; H05K 7/14

(52) U.S. Cl. CPC G02B 6/44528; G02B 6/4257; G02B 6/4261; G02B 6/4446; H05K 7/1489; H05K 7/1492

(57) ABSTRACT

Methods and apparatus for integrated optical fiber shuffle harness for switch and compute trays. An optical fiber shuffle harness comprises a housing having front and back walls, a first plurality of optical fiber connectors installed in the front wall, a second plurality of optical fiber connectors installed in the back wall, and a plurality of optical fibers. Groups of optical fibers are coupled as bundles to the optical fiber connectors installed in the front wall and pairs of transmit (Tx) and receive (Rx) optical fibers in bundles are routed to different optical fiber connectors installed in the back wall such that the routing of optical signals within the optical fiber shuffle harness are shuffled. The optical fiber shuffle harness may also include one or more optical isolator boxes that are used for isolating Tx signals. Optical fiber shuffle harnesses may be implemented in switch trays, chassis, and sleds.

### BACKGROUND INFORMATION

The use of cloud-based computing has become ubiquitous in recent years. With the introduction of artificial intelligence (AI) platforms, the demand for cloud computing has accelerated with building of new data centers and dozens of data centers planned to be online in the coming years.

To support AI cloud-hosted services, these data centers have hundreds or thousands of racks populated with compute, memory, and storage resources. For AI, the compute resources include graphic processing units (GPUs) that have internal architectures that are well-suited for implementing machine learning and AI models using neural networks.

In a traditional system, the system elements are connected many individual fibers for point-to-point connections that can become very complex and prone to human errors, especially when adding/removing/upgrading system elements. Such systems become exponentially complex and error-prone as they scale to accommodate tens of thousands of individual fibers. In large-scale deployments, the sheer volume of fiber management creates a web of complexity that is highly susceptible to human error during installation, maintenance, and troubleshooting. Consider a centralized 2-tier system using 128-port switches connecting to 512 endpoints, each requiring 16 fiber pairs-this configuration demands managing over 8,000 individual fiber connections in massive, unwieldy bundles that converge at central distribution points. The complexity multiplies when technicians must trace specific fibers through these enormous harnesses, leading to increased installation time, higher error rates, and significant downtime during maintenance operations.

Even scaling down to a 64-port, 2-tier centralized system still presents substantial challenges, as thousands of fibers must still be routed through central chokepoints, creating physical constraints and maintenance nightmares.

### BRIEF DESCRIPTION OF THE DRAWINGS

The foregoing aspects and many of the attendant advantages of this disclosure will become more readily appreciated as the same becomes better understood by reference to the following detailed description, when taken in conjunction with the accompanying drawings, wherein like reference numerals refer to like parts throughout the various views unless otherwise specified:

FIG. 1 is a schematic diagram illustrating a system including compute trays, a copper cable wall, a leaf switch tray including an optical fiber shuffle harness, and a spline switch tray including an optical fiber shuffle harness, according to one embodiment;

FIG. 2 is a schematic diagram of a switch tray including an optical fiber shuffle harness, according to one embodiment;

FIG. 2a is a schematic diagram of a switch tray illustrating a variation of the switch tray in FIG. 2 under which the front wall of the switch tray serves as the front wall for the optical fiber shuffle harness, according to one embodiment;

FIG. 3 shows a front view of the switch tray of FIGS. 2 and 2a, according to one embodiment;

FIG. 4 shows a rear view of the switch tray of FIGS. 2 and 2a, according to one embodiment;

FIG. 5a is a schematic diagram of an electrical-to-optical (e2o) switch module comprising a hybrid switch or repeater, according to one embodiment;

FIG. 5b is a schematic diagram of an optical-to-optical (o2o) switch module, according to one embodiment;

FIGS. 6a and 6b respectively show perspective and plan views of an optical fiber shuffle harness with the optical fibers removed, according to one embodiment;

FIG. 7 shows a 3D view of an optical isolator box, according to one embodiment;

FIG. 8 is a diagram illustrating routing paths for optical fiber bundles and transmit (Tx) and receive (Rx) optical fiber pairs illustrating cross connection of routing paths in a first shuffle pattern, according to one embodiment;

FIG. 8a is a diagram illustrating routing paths for optical fiber bundles and Tx and Rx optical fiber pairs illustrating cross connection of routing paths in a second shuffle pattern under which optical fibers from multiple fiber bundles are routed through a shared optical isolator box, according to one embodiment;

FIG. 8b is a diagram illustrating routing paths for bi-directional optical fibers illustrating cross connection of routing paths in a third shuffle pattern, according to one embodiment;

FIG. 9 is a diagram of a system including a plurality of racks in which compute blades and e2o switch sleds are installed, an O2O rack in which o2o switch trays are installed and optical cables coupling e2o switch sleds to o2o switch trays;

FIG. 10 is a diagram illustrating further details of compute blades, e2o switch sleds, and interconnection between compute blades and e2o switch sleds, according to one embodiment;

FIG. 11 shows an expanded frontal view of the O2O rack, according to one embodiment;

FIG. 12 shows a front elevation view of an o2o switch tray in the O2O rack, according to one embodiment; and

FIG. 13 shows a model of a system installed in a data center including 8 racks in which compute trays and e2o switch trays are installed, an O2O rack in which o2o switch trays are installed, and optical cables interconnecting e2o switch trays to o2o switch trays.

### DETAILED DESCRIPTION

Embodiments of methods and apparatus for integrated optical fiber harness for switch and compute trays are described herein. In the following description, numerous specific details are set forth to provide a thorough understanding of embodiments disclosed herein. One skilled in the relevant art will recognize, however, that the embodiments can be practiced without one or more of the specific details, or with other methods, components, materials, etc. In other instances, well-known structures, materials, or operations are not shown or described in detail to avoid obscuring aspects of the embodiments.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

In accordance with aspects of the embodiments disclosed herein, an integrated fiber harness that functions as a distributed fiber harness is provided that is used to replace complex and expensive centralized fiber harnesses. In stark contrast, to the example above 8000 fibers centralized fiber harness, a distributed fiber harness architecture transforms this complexity by organizing both endpoints and switches into logical groups (e.g., 4), with fiber pairs bundled accordingly into manageable fiber bundles. This distributed approach breaks the monolithic fiber management problem into smaller, independent bundles that can be routed, installed, and maintained separately. Each bundle contains only the fibers relevant to its specific group, dramatically reducing the potential for human error, simplifying troubleshooting to specific zones, and enabling parallel installation and maintenance activities. The result is a more resilient, maintainable system where technicians work with clearly defined, small-scale fiber groups rather than navigating through thousands of fibers in centralized harnesses.

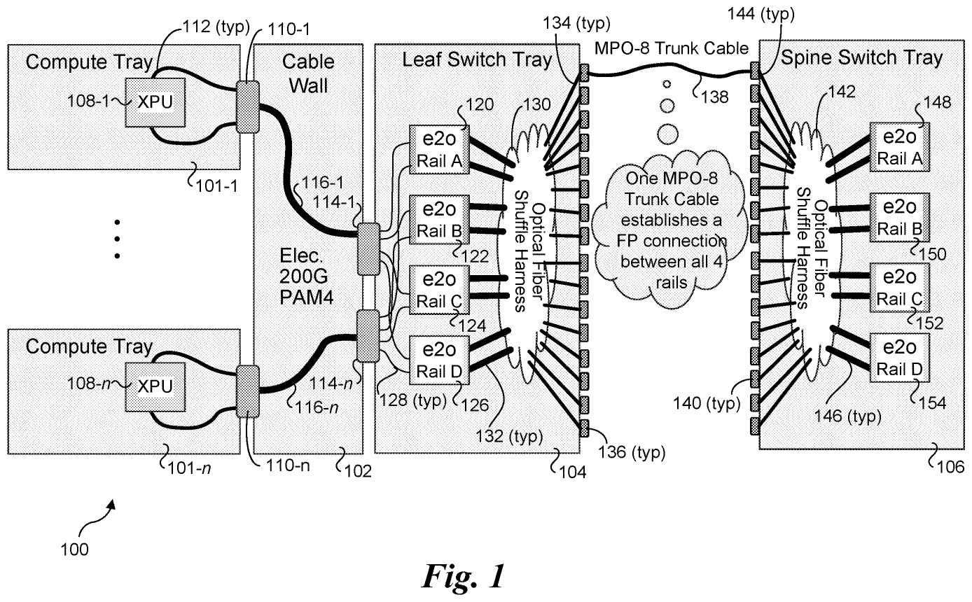

FIG. 1 shows a system 100 including n compute trays 101-1 . . . 101-n, a cable wall 102, a leaf switch tray 104, and a spline switch tray 106. Each of compute trays 101-1 . . . 101-n, includes a plurality of Other Processing Units (XPUs) trays 108-1 . . . 108-n of which a single XPU is illustrated for convenience. Other Processing Units (collectively termed XPUs) include one or more of Graphic Processor Units (GPUs) or General Purpose GPUs (GP-GPUs), Tensor Processing Units (TPUs), Data Processing Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of GPUs, this is merely exemplary and non-limiting. Generally, any type of XPU may be used in place of a GPU in the illustrated embodiments. Moreover, as used in the following description and claims, the term “processor” is used to generically cover central processing units (CPUs) and various forms of XPUs. n connectors 110-1 . . . 110-n are shown on the left side of cable wall 102, with the XPUs 108 coupled to connectors 110-1 . . . 110-n via applicable cables 112 and/or wiring in the circuit board on which the XPUs are installed. A pair of connectors 114-1 and 114-n are shown on the right side of cable wall 102 for illustrative purposes. In some embodiments there will be the same number of connectors 110 and 114 while in other embodiments there will be more connectors 110 than 114. There is a respective cable bundle 116-1 and 116-n coupled between respective pairs of connectors 110-1 and 114-1 and 110-n and 114-n.

Leaf switch tray 104 is depicted as including four electrical-to-optical (e2o) rails 120, 122, 124, and 126, also respectively labeled e2o rails A, B, C, and D. These e2o rails are coupled to connectors 114-1 and 114-n via cables 128 on the left-hand side and connected to an optical fiber shuffle harness 130 via cable bundles 132 on the right-hand side. Optical fiber shuffle harness 130 is connected to respective optical cable ports 136 via respective optical fiber bundles 134.

Spine switch tray 106 include components that are arranged in mirrored configuration to analogous components in leaf switch tray 104. These components include optical cable ports 140 that are connected to the left-hand side of an optical fiber shuffle harness 142 via respective optical fiber bundles 144, and e2o rails 148, 150, 152, and 154 (also labeled e2o rails A, B, C, and D) that are coupled to the right-hand side of optical fiber shuffle harness 142 via optical fiber bundles 146.

As further shown, pairs of optical cable ports 136 and 140 are coupled via MPO-8 trunk cables 138. Through cross connections in the optical fiber shuffle harnesses 130 and 142, one MPO-8 trunk cable may be used to establish FP connections between all 4 rails in leaf switch tray 104 and spine switch tray 106.

In the illustrated embodiment, the electrical cables and signal paths are used to implement 200 Gigabits per second (200 G) PAM4 encoded signals that are sent over 200 G PAM4 copper cables, where 200 G is a generic term with actual raw date rates of 212.5 G or 224 G. 200 G PAM4 signals can be implemented under multiple lanes on respective copper cables to multiply the bit rate up to 800 G, which a signal bandwidth of 200 G per lane. For a bi-directional link there would be a set of 4 lanes for each direction. Under optional configurations, the deployment may include a cable wall, midplane, or a direct orthogonal design (leaf switch trays connect directly to compute trays).

An MPO-8 cable is an 8-fiber Multi-fiber Push-On (MPO) high-density fiber optic cable that provides 8 fibers in a signal cable that may be coupled to single, compact MPO-8 connectors. They are commonly used with QSFP optical transceivers (4 transmitting and 4 receiving), utilizing all 8 optical fibers. They may be used with other optical transceivers, as well.

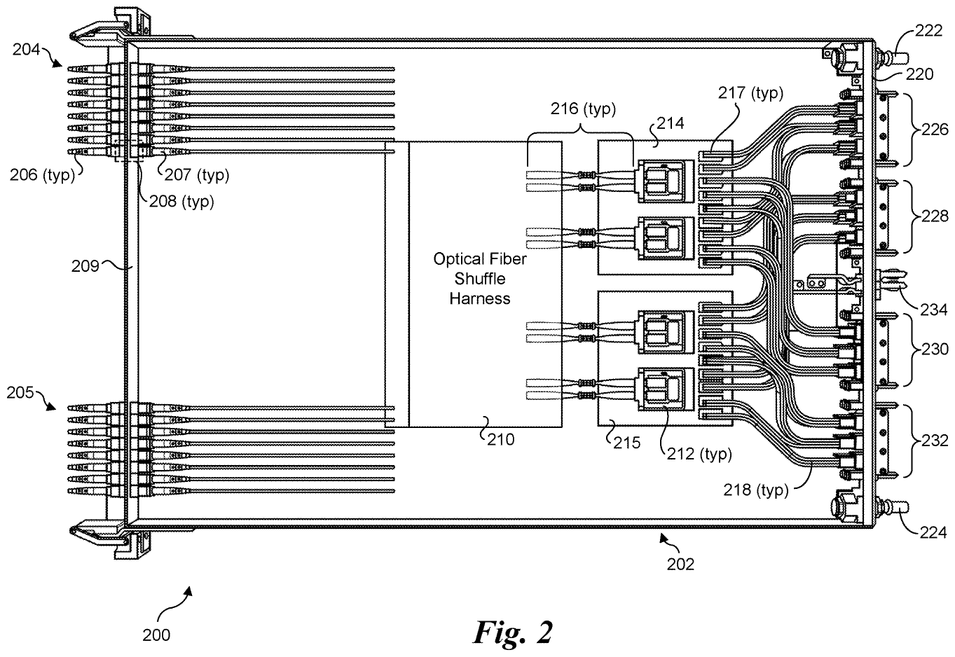

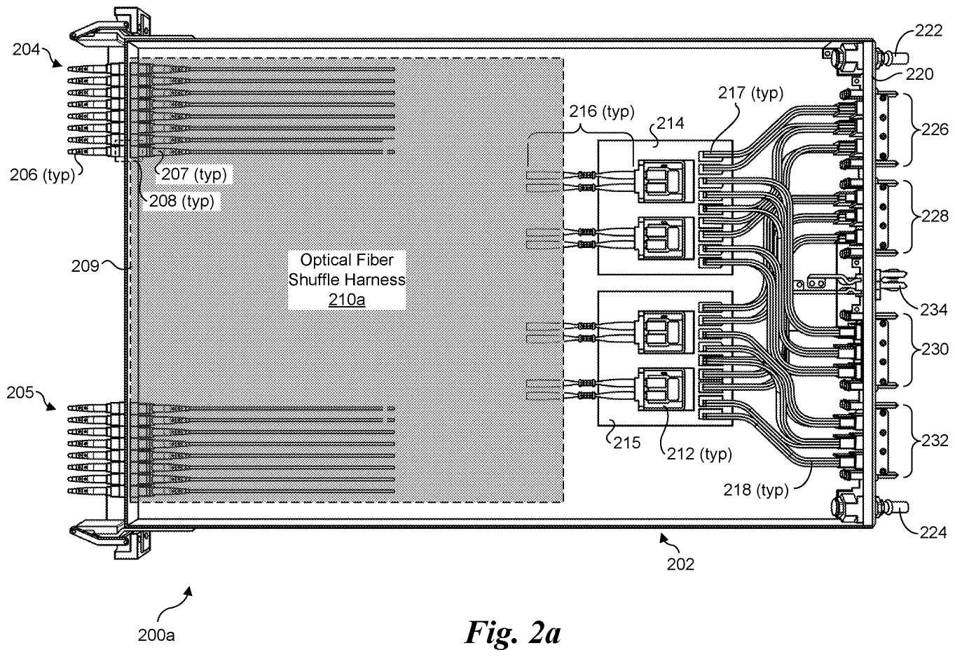

FIG. 2 shows a switch tray 200, in accordance with one embodiment. Switch tray 200 includes a tray frame 202 having a flat bottom, side walls, and front and end walls. Trays may also be referred to as chassis and/or sleds, depending on the rack configuration, where the terms “trays,” “chassis,” and “sleds” may be used interchangeable in the following description and claims. At the left end of switch tray 200 are groups of 8 optical to spine connection 204 and 205. Each optical spine connection includes an external optical cable 206 and internal optical cable 207, each having connector ends coupled to an optical connector 208 that is mounted within an aperture in front wall 209.

Toward the middle of switch tray 200 is an optical fiber shuffle harness 210, which is used to cross connect various optical fiber signal paths, as described and illustrated below. Switch tray 200 also includes optical switch modules 212 mounted to optical switch module sub-boards 214 and 215. Fiber bundles 216 are coupled between connectors (not shown) in optical fiber shuffle harness 210 and optical switch modules 212.

Various components are mounted through end wall 220, including a pair of docking liquid cooling quick disconnects (LCQD)s 222 and 224, cable cartridge interfaces 226, 228, 230, and 232, and a power buss bar connector 234. Multiple flyover twinax cable harnesses 218 are connected between connectors 217 on optical switch module sub-boards 214 and 215 and connectors on the internal side of cable cartridge interfaces 226, 228, 230, and 232. As shown, the routing of flyover twinax cable harnesses 218 are cross connected such that signals from the pair of optical switch modules 212 on each of optical switch module sub-boards 215 and 215 are connected to a connector for each of cable cartridge interfaces 226, 228, 230, and 232.

In addition to the circuitry shown in FIG. 2, a switch tray may have other components that are not shown for clarity. This includes various components used for liquid cooling components in switch tray 200.

In one embodiment, cable cartridge interfaces support 72 lanes of 200 G PAM4 signals. In one embodiment on the external side the cable cartridge interface is configured as three groups of 24 lanes and are configured to mate with a mating male connector in which a bundle of 72 electrical cables (e.g., copper cables) is coupled. This is merely exemplary and none limiting, as other numbers of lanes and numbers of optical fibers may be used, as will be recognized by those skilled in the art. In this illustrated embodiment, each flyover twinax cable harnesses 218 includes wired cables for 24 200 G PAM4 signal lanes. Under this embodiment, the switch modules 212 are 72 lane 200 G electrical/800 G optical e2o switch modules.

For o2o switch trays, switch modules 212 are o2o (optical-to-optical) switch modules. In this embodiment, flyover twinax cable harnesses would be replaced with optical fiber cable harnesses or the like and the cable cartridge interfaces would be configured to mate with male connectors for optical fiber cables rather than electrical cables.

FIG. 2a shows an alternative configuration for a switch tray 200a under which front wall 209 also serves as the front wall for optical fiber shuffle harness 210a. An advantage of this configuration over switch tray 200 is there do not need to be any optical fibers coupled between connectors in the front wall of the switch tray and the front wall of the optical fiber shuffle harness.

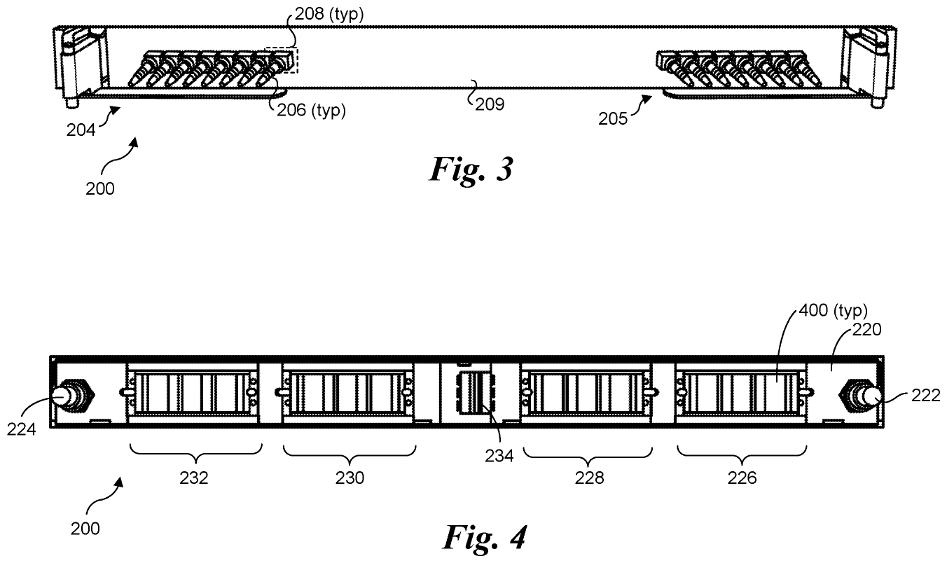

FIGS. 3 and 4 respectively show front and rear views of switch tray 200. As shown in FIG. 3, optical connectors 208 are installed in and pass through end wall 209 and the connector ends of optical fiber cables 206 are coupled with respective optical connectors 208. In FIG. 4, each cable cartridge interfaces 226, 228, 230, and 232 includes three connection receptacles 400. In one embodiment, each of connection receptacles 400 is configured to mate with a mating connection plug that is part of the cable cartridge that would be inserted into cartridge interfaces 226, 228, 230, and 232.

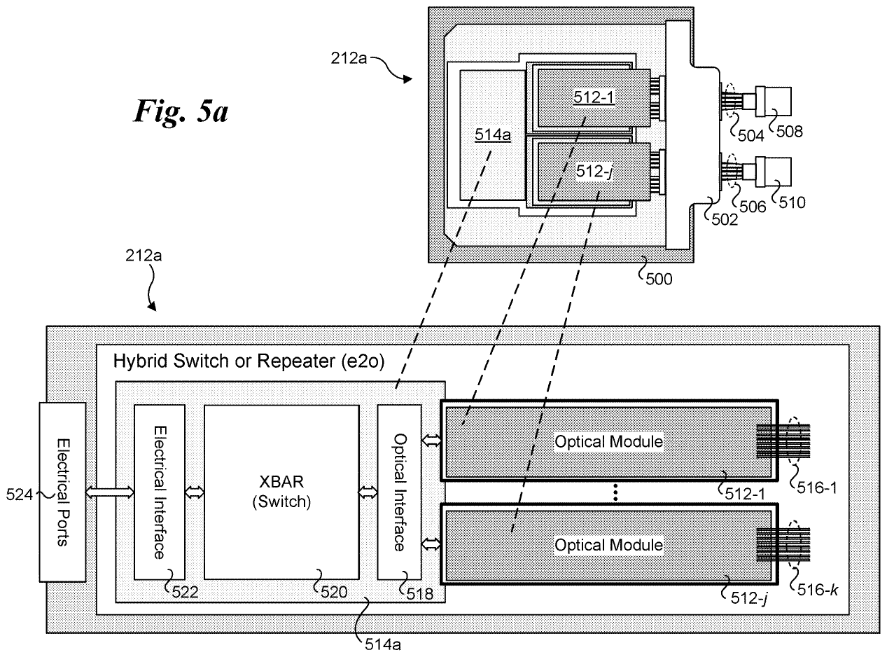

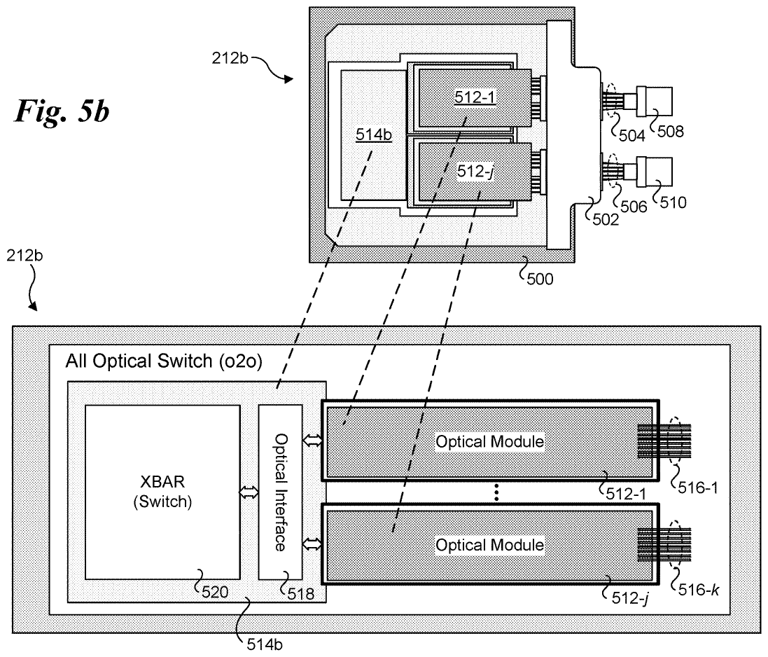

FIG. 5a shows details of an e2o switch module 212a, according to one embodiment. The e2o switch module may be implemented as a hybrid switch or a repeater. An e2o switch module provides switch functionality that enables selective connections between electrical signals and optical signals.

The e2o switch module includes multiple components that are mounted to a sub-board 500 including a fabric bundles interface 502 in which multiple fabric bundles are coupled, as shown by fabric bundles 504 and 506, which are respectively coupled to respective couplers 508 and 510. In the illustrated embodiment there are two fiber bundles coming into the fabric bundles interface 502, while generally there could be m fiber bundles where m represented an integer.

The illustrated embodiment depicts a pair of optical modules 512-1 and 512-j that is presentative of a number j of optical modules 512. Each optical module may receive one or more fiber bundles 516, as depicted by fiber bundles 516-1 and 516-k, where j and k may be the same number of may be different numbers.

The optical modules provide optical signals that are passed between each optical module 512-1 and 512-j and an optical interface block 518 on a front-end die 514a. Other circuit blocks on front-end die 514a include a cross-bar (XBAR) switch 520 and an electrical interface 522. XBAR switch 520 includes a plurality of inputs and outputs that are cross-connected internally with signal paths that can be selectively routed between pairs of input and outputs. Electrical interface 522 converts optical signals to electrical signals and is coupled to electrical ports 524 that are adjacent to e2o switch module 212a, such as depicted by connectors 217 in FIG. 2.

FIG. 5b shows an o2o switch module 212b, according to one embodiment. Components with the same reference numbers in e2o switch module 212a and o2o switch module 212b are the same in both switch modules. The difference is front-end die 514b operates entirely within the optical domain and thus does not include an electrical interface 522. It is further noted that while a single optical interface block 518 is shown in FIG. 5b there may be multiple optical interfaces that are physically located on two or more sides of XBAR switch 520.

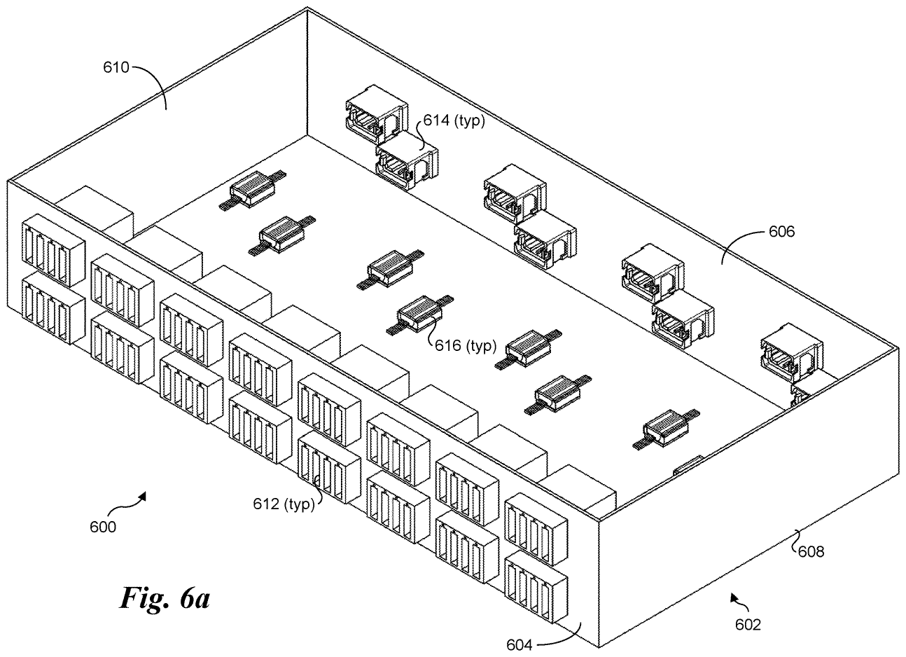

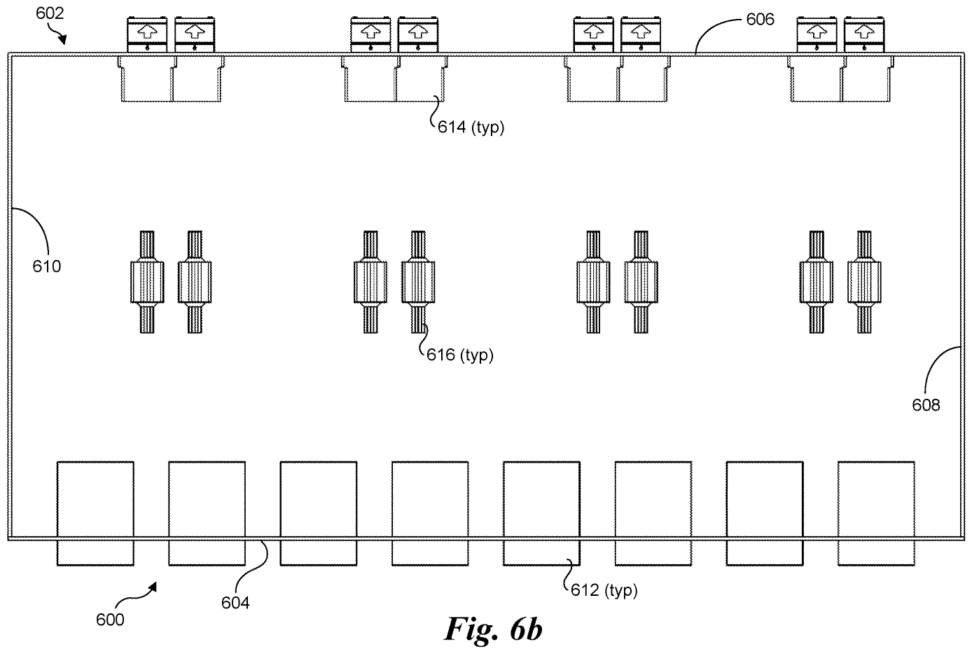

FIGS. 6a and 6b shows views of optical fiber shuffle harness 600, according to one embodiment. Optical fiber shuffle harness 600 includes a housing 602 having front and end walls 604 and 606 and side walls 608 and 610. The housing may optionally include a lid that is not shown. A first plurality of optical connectors 612 are mounted to (and pass through) front wall 604. A second plurality of optical connectors 614 are mounted to (and pass through) end wall 606. Optical fiber shuffle harness 600 also includes multiple optical isolators boxes 616.

In this exemplary embodiment, optical connectors 612 are MPO-8 connectors. In one embodiment, optical connectors 614 are MPO-16 connectors that are configured to mate with an MPO-16 bayonet connector. Other optical connectors may also be used, as will be recognized by those skilled in the art.

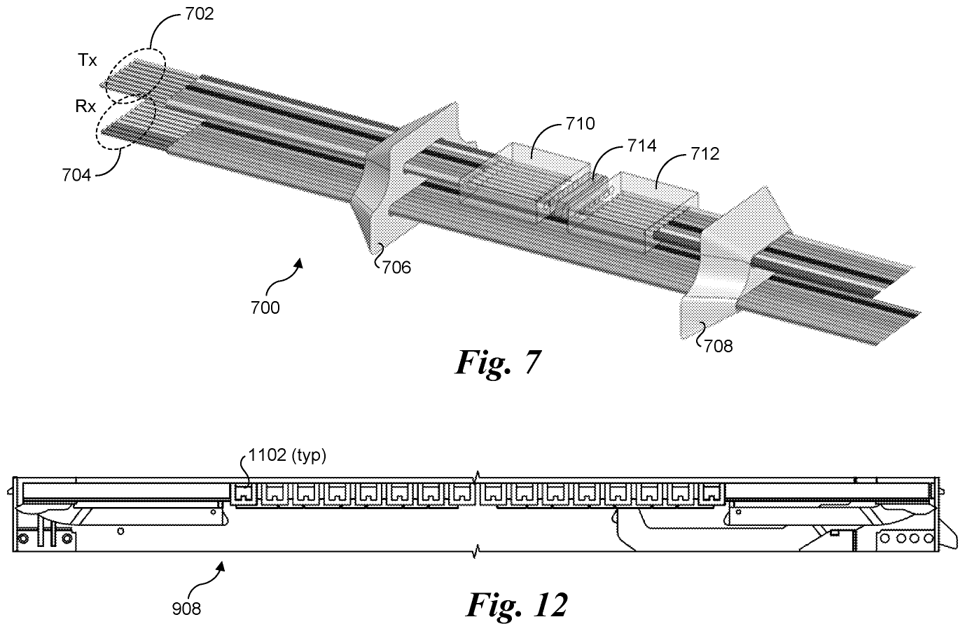

FIG. 7 shows an optical isolator box 700 with the box body and lids removed for clarity, according to one embodiment. The optical isolator box is used to provide optical signal isolation for transmit (Tx) signals that are transmitted through respective Tx optical fibers 702. Under typical optical cable paths, the optical fibers within an optical cable will include one or more optical fibers for transmitting signals and one or more optical fibers for receiving signals, thus enabling a given optical cable to support bi-directional communication. Since optical signal isolation is only used for Tx signals, the receive (Rx) optical fibers 704 do not use signal isolation, in the illustrated embodiment.

In the illustrated embodiment, the respective Tx and Rx optical fibers are configured to support 400 G, 800 G, or 1600 G signaling. Other signal bandwidths may also be used.

Tx optical fibers 702 and Rx optical fibers 704 pass through apertures in end blocks 706 and 708, which are disposed at respective ends of a housing (not shown) containing lens ferrules 710 and 712 and an optical isolator block 714. Each of lens ferrules 710 and 712 include an array of cylindrical lens that include a respective means for coupling with an optical fiber at one end and a lens at the other end. The lens ends for lens ferrules 710 and 712 are on opposing sides of optical isolator block 714 and oriented 180 degrees relative to one another along their longitudinal axes. The optical isolator block 714 may comprise an optical waveplate having suitable thickness and made of a suitable material such as quartz (crystalline SiO₂) in one embodiment, noting the relative thickness depicted for optical isolator block 714 is not to scale.

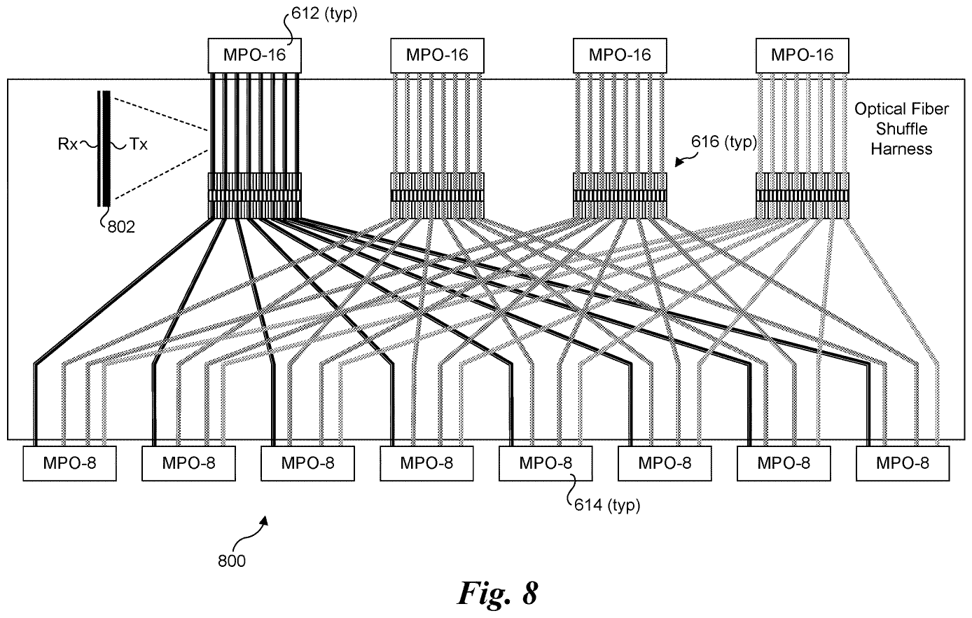

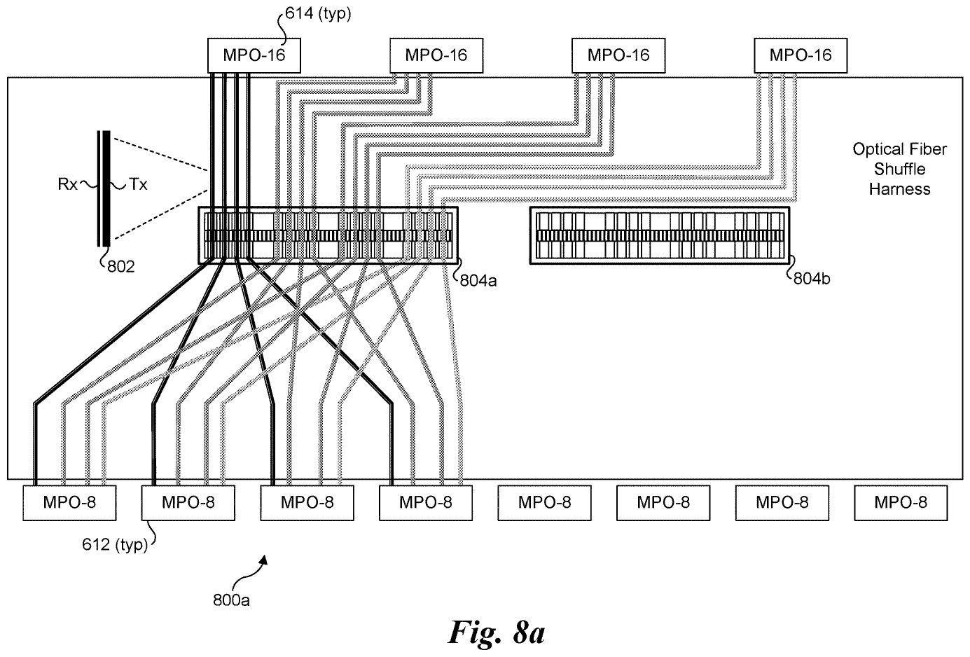

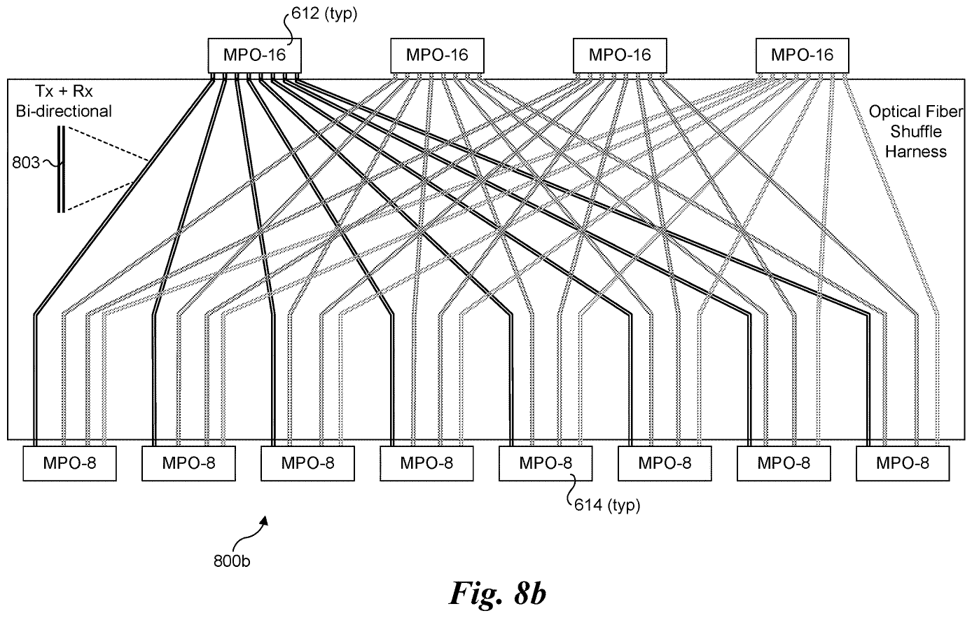

FIG. 8 shows a schematic representation 800 of optical fiber routing paths through an optical fiber shuffle harness, according to one embodiment. In this example, optical connectors 612 are MPO-16 connectors while optical connectors 614 are MPO-8 connectors. Each of the optical path segments 802 includes a pair of optical fibers for conveying Tx signals and Rx signals. With respect to the optical fiber shuffle harness embodiment illustrated in FIGS. 6a and 6b, there would be two instances of what is shown in FIG. 8. As shown in FIG. 7 and discussed above, in one embodiment the Tx optical fibers would be routed above the Rx optical fibers for portions of the optical path segments proximate to and passing through optical isolator boxes 616. In this embodiment, there is an optical isolator for respective sets of 8 Tx fibers.

As illustrated by the routing paths in FIG. 8, for each MPO-16 connector 612 the 8 Tx/Rx pair of fibers coupled to the connector are respectively routed to different MPO-8 connectors after being routed through their associated optical isolator box 616.

FIG. 8a shows a schematic representation 800a of optical fiber routing paths where optical fibers from multiple MPO-16 connectors 614 are routed through (and Tx signals are isolated for) optical isolator boxes 804a and 804b. The four Tx/Rx optical fiber pairs for each of MPO-16 connectors 614 are removed for clarity. It will be understood that those Tx/Rx optical fiber pairs would be routed through optical isolator box 804b to the four MPO-8 connectors 612 toward the bottom right FIG. 8a. For optical fiber shuffle harness 600 shown in FIGS. 6a and 6b there would be four instances of the optical fiber routing paths shown.

In addition to deployments using separate Tx and Rx fibers, some embodiments may use bi-directional fibers that are used for both Tx and Rx signals. FIG. 8b shows a schematic representation 800b of optical fiber routing paths where optical fibers 803 are bi-direction optical fibers used for both Tx and Rx signals. Under embodiments using bi-directional fibers isolation of Tx signal may be implemented at some point in the signal path that is external to the optical fiber shuffle harness.

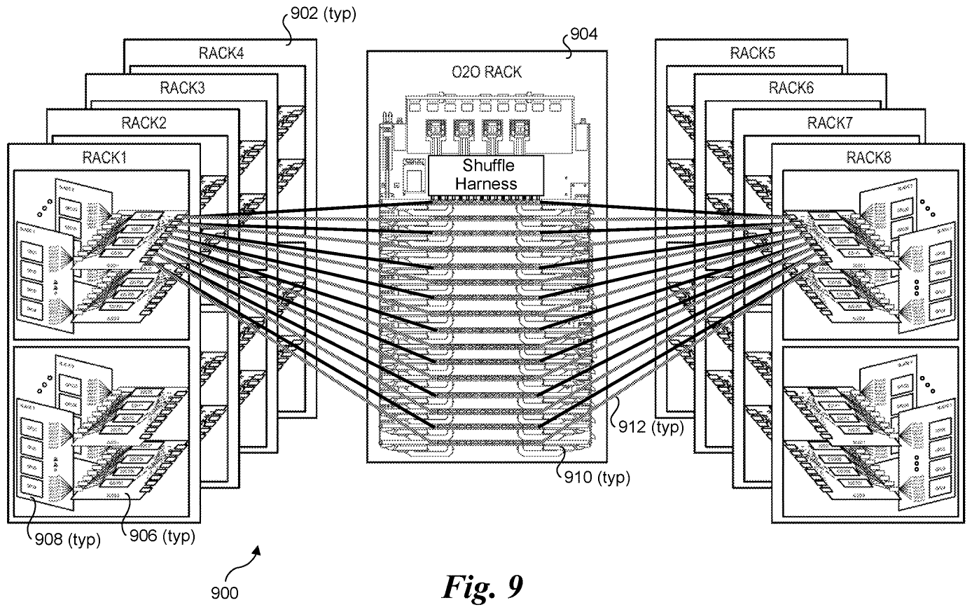

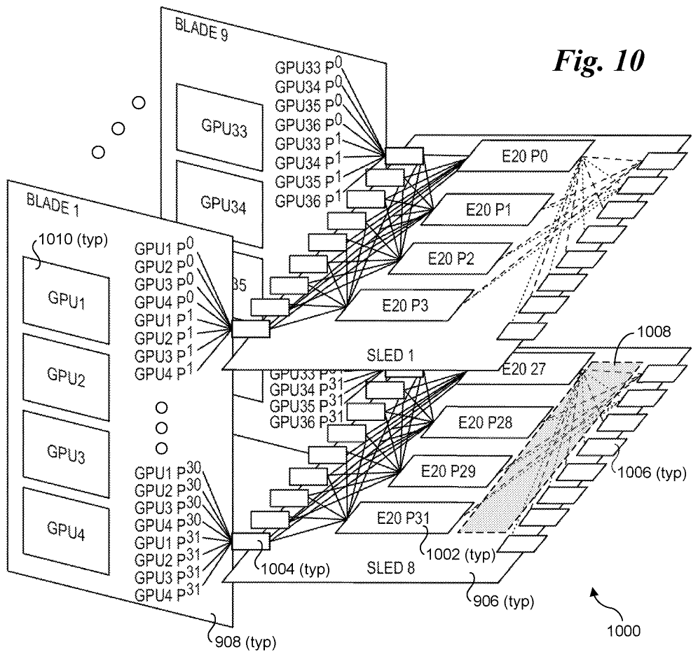

FIG. 9 shows a system 900 in which optical fiber shuffle harnesses are implemented. System 900 includes 8 racks 902 (also labeled RACK1, RACK2, . . . RACK 8) and an O2O RACK 904. Each of racks 902 includes multiple e2o switch sleds 906 and GPU blades 908, further details of which are shown in FIG. 10. O2O rack 904 includes 16 o2o switch trays 910. Optical connector ports on e2o switch sleds 906 are connected to optical connector ports on o2o switch trays 910 via optical cables 912.

FIG. 10 shows a diagram 1000 illustrated further details e2o sleds 906 and GPU blades 908, according to one embodiment. The e2o sleds are numbered 1-8 (e.g., SLED 1 . . . SLED 8) and the GPU blades are likewise numbered 1-9 (e.g., BLADE 1 . . . BLADE 9). In one embodiment, each rack 902 includes 8 e2 o switch sleds and 9 compute sleds. A respective e2o switch tray is installed in each e2o switch sled while a respective GPU blade tray is installed in each compute sled.

Each e2o sled includes four e2o rails 1002 labeled E2O P0 . . . E2O P31 for a total of 32 e2o rails in a rack. Each e2o rail 1002 is connected to 9 electrical ports 1004 and 8 optical ports 1006. The connections between e2o rail 1002 and optical ports 1006 represent an abstracted view of the optical fiber routing in an optical fiber shuffle harness 1008.

Each GPU blade 908 is depicted as including four GPUs 1010, with the GPUs across the 9 GPU blades numbered GPU¹ . . . GPU³⁵. There are 32 rails for each GPU, as depicted by GPU1^{P0}, GPU2^{P0} . . . GPU1^{P1} . . . GPU1^{P30} . . . GPU4^{P31}. Groups of GPU rails are connected to electrical ports 1004.

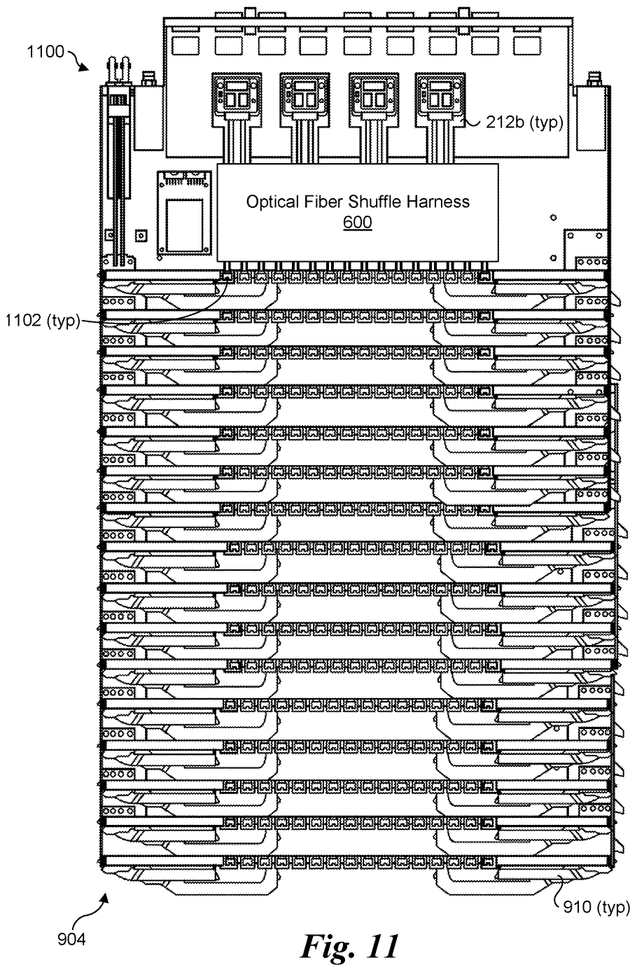

FIGS. 11 and 12 show further details of the O2O rack 904 and the o2o switch trays installed in the rack. In FIG. 11, the top o2o switch tray 1100 is rotated forward 90 degrees such that the circuitry is shown from the perspective of a plan view. Each o2o switch tray 910 includes 16 optical connectors 1102 that are cross-connected to o2o switch modules 212b via optical fibers that are appropriately routed in optical fiber shuffle harness 600 in the manner described and illustrated above.

Returning to FIG. 9, similar sets of optical cables 912 would be coupled between the optical ports on the E2O switch sleds 906 and the optical connectors 1102 on the o2o switch trays 910. When fully populated and interconnected with optical cables system 900 supports interconnection of 576 GPUs using only 512 optical cables 912.

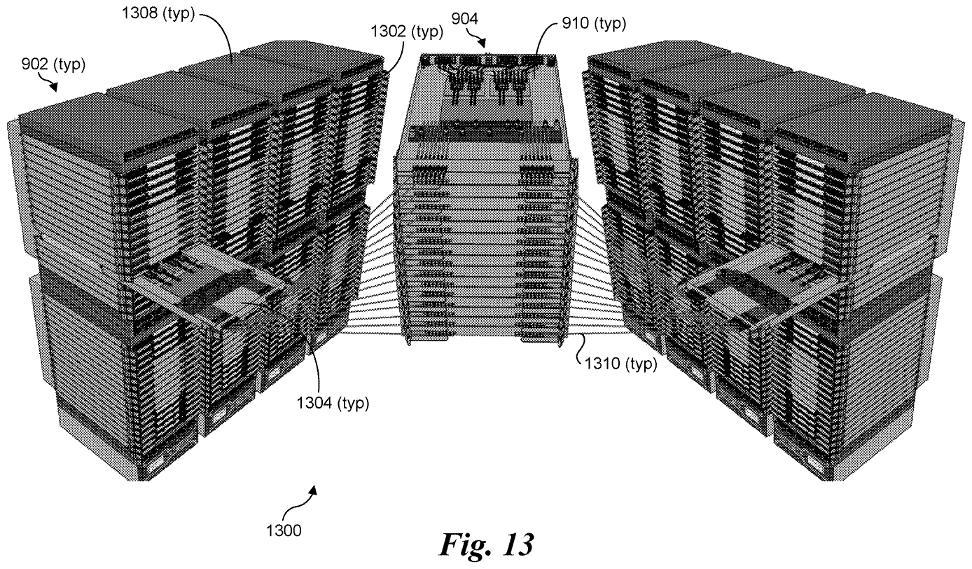

FIG. 13 shows a 3D perspective view of a system 1300 including 8 racks 902, an O2O rack 904. Each rack 902 is populated with 9 compute trays 1302 and 8 e2o switch trays 1304. At the top of each rack 902 is a Top-of-Rack (TOR) switch 1308. There is cabling at the back of each rack that couples the compute trays to TOR switch 1308, which facilitates communication between compute resources on the compute trays. As illustrated in FIG. 10, there is also cabling in the back of each rack 902 that communicatively couples e2o switch trays 1304 to compute trays 1302. As represented by optical cables 1310, there would be a similar set of optical cables coupled between each e2o switch tray 1304 and the o2o switch trays 910.

The principles and teachings disclosed herein provide significant improvement to existing approaches for interconnecting compute resources in data center environment. This includes aggregating multiple devices into a single optical trunk cable for ease of system cabling, reducing the number of trunk cables required. The system can included isolators necessary for ISL, and isolators can be implemented as part of the shuffle solution. The approach replaces complex and expensive centralized fiber harnesses with distributed fiber harness on each tray including K elements (e.g., leaf switches, spine switches, XPU end points).

Direct fiber connection (no centralized, external harness) between each leaf with m elements, each with y fibers to each of the x spines carrying n elements-total links in the system m*y=x*n, and the total fiber bundles per each ply=x (number of destinations). As used herein, a N-ply communication means there are N independent paths available for communication between nodes.

The solutions provided by the principles and teachings disclosed herein are not limited to switching, but can apply to any design that integrate multiple elements (e.g., XPU) with optical connections. In addition, the solutions allow for replaceable E2O module sub-boards. The solution also provides replaceability at the harness level by using the isolator as part of the fiber shuffle solution. The integrated fiber harness also reduces the fiber bending angle needed, can be used to accommodate redundancy in fibers and or sources. Additionally, the harness eliminates the exposure of isolator to high temperature assembly processes by separating the module assembly from the harness physical assembly.

While various embodiments described herein use the term System-on-a-Chip or System-on-Chip (“SoC”) to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

The following examples pertain to additional examples of the teachings and principles disclosed herein.

Example 1. An apparatus, comprising an optical fiber shuffle harness including, a housing having front and back walls, a first plurality of optical fiber connectors installed in the front wall, at least a portion of which have an external port and an internal port coupled to a plurality of internal optical fibers disposed within the housing, and a second plurality of optical fiber connectors installed in the back wall, at least a portion of which include an external port and an internal port coupled to optical fibers among the plurality of internal optical fibers. The internal optical fibers are cross-connected such that, for each of at least a portion of the first plurality of optical connectors, multiple optical fibers are connected at a first end to the optical connector and respective optical fibers among the multiple optical fibers are connected at second ends to respective optical connectors among the second plurality of optical connectors.

Example 2. The apparatus of example 1, wherein a first portion of the plurality of internal optical fibers are transmit (Tx) optical fibers configured for transmitting optical signals and a second portion of the plurality of internal optical fibers are receive (Rx) optical fibers configured for receiving optical signals.

Example 3. The apparatus of example 2, further comprising a plurality of optical isolator boxes, wherein at least a portion of the Tx optical fibers are optically coupled via an optical isolator box among the plurality of optical isolator boxes.

Example 4. The apparatus of example 3, wherein an optical isolator box comprises a first lens ferrule having a plurality of optical lenses configured at a first end to be coupled to a respective Tx optical fiber in a first bundle of Tx optical fibers and having a lens at a second end, the first lens ferrule configured in a first longitudinal direction. The apparatus also includes a second lens ferrule oriented 180 degrees relative to first longitudinal direction and having a plurality of optical lenses configured at a first end to be coupled to a respective Tx optical fiber in a second bundle of Tx optical fibers and having a lens at a second end, and an optical isolator block or plate, disposed between the lenses on the first and second lens ferrules.

Example 5. The apparatus of example 4, wherein the optical isolator includes a first end block and a second end block, each having first apertures through which a respective bundle among the first and second bundles of Tx optical fibers pass and second apertures through which a bundle of Rx optical fibers pass.

Example 6. The apparatus of any of the preceding examples, wherein the internal optical fibers are fully cross connected such that when external optical fiber bundles are installed in respective external receptacles for each of the first plurality of optical fiber connectors and when external optical fibers bundles are installed in respective external receptacles for each of the second plurality of optical fiber connectors, each optical fiber in an external optical fiber bundles for a given external port for an optical fiber connector in the first plurality of optical fiber connector is coupled via a respective signal path to an optical fiber in a respective optical fiber bundle connected to the respective second plurality of optical fiber connectors.

Example 7. The apparatus of any of the preceding examples, wherein the apparatus is a switch tray or sled, further comprising a plurality of electrical to optical (e2o) switch modules, each e2o switch module coupled to at least one optical fiber bundle coupled to a respective external receptacle of an optical fiber connector in the second plurality of optical fiber connectors.

Example 8. The apparatus of example 7, wherein the switch tray or sled includes a tray, chassis, or sled having a plurality of cable interfaces installed in an end of the tray, chassis, or sled, and wherein an e2o switch module includes an electrical interface via which signals from plurality of cables coupled between the electrical interface and a portion of the cable interfaces are electrically coupled.

Example 9. The apparatus of any of the preceding examples, wherein the apparatus is a switch tray or sled, further comprising a plurality of optical to optical (o2o) switch modules, each o2o switch module coupled to at least one optical fiber bundle coupled to a respective external receptacle of an optical fiber connector in the second plurality of optical fiber connectors.

Example 10. The apparatus of any of the preceding examples, wherein the apparatus is a switch tray or sled having a front wall comprising the front wall of the optical fiber shuffle harness housing.

Example 11. A system, comprising a first rack, including a first plurality of compute trays, each including a plurality of other processing units (XPUs) and a plurality of electric cable ports, a plurality of electrical-to-optical (e2o) switch trays, each having a plurality of electric cable ports and a plurality of optical cable ports, a plurality of e2o switch modules and an optical fiber shuffle harness, and a plurality of electrical cables connecting electric cable ports on the compute trays to electric cable ports on the plurality of e2o switch trays. The system also has a second rack, including a plurality of optical-to-optical (o2o) switch trays, each including, a plurality of optical fiber ports installed on a frontside wall, the optical fiber ports having an internal port and an external port, an optical fiber shuffle harness, and a plurality of (o2o) switch modules. The system uses a plurality of optical cables coupled between optical cable ports on the e2o switch trays and optical cable ports on the o2o switch trays.

Example 12. The system of example 11, wherein an optical fiber shuffle harness comprises a housing having front and back walls, a first plurality of optical fiber connectors installed in the front wall, a second plurality of optical fiber connectors installed in the back wall, and a plurality of optical fibers, wherein groups of optical fibers are coupled as bundles to the optical fiber connectors installed in the front wall and wherein pairs of transmit (Tx) and receive (Rx) optical fibers in a given bundle are routed to different optical fiber connectors installed in the back wall such that the routing of optical signals within the optical fiber shuffle harness are shuffled.

Example 13. The system of example 12, wherein at least a portion of the optical fiber shuffle harnesses include one or more optical isolator boxes configured to optically couple first and second segments of Tx optical fibers.

Example 14. The system of example 13, wherein an optical isolator box comprises a first lens ferrule having a plurality of optical lenses configured at a first end to be coupled to a respective Tx optical fiber in a first bundle of Tx optical fibers and having a lens at a second end, the first lens ferrule configured in a first longitudinal direction, a second lens ferrule oriented 180 degrees relative to first longitudinal direction and having a plurality of optical lenses configured at a first end to be coupled to a respective Tx optical fiber in a second bundle of Tx optical fibers and having a lens at a second end, and an optical isolator block or plate, disposed between the lenses on the first and second lens ferrules.

Example 15. The system of any of examples 11-14, wherein each of at least one of the e2o switch trays or o2o switch trays includes a front wall that also serves as the front wall of the optical fiber shuffle harness for that e2o or o2o switch tray.

Example 16. A method implemented in a switch tray, chassis, or sled having a plurality of switch modules and including an optical fiber shuffle harness having a plurality of frontside optical connectors installed in a front wall and a plurality of backside optical connectors installed in a back wall. The method comprises coupling optical fiber bundles to respective frontside optical connectors, each optical fiber bundle including at least four pairs of transmit (Tx) and receive (Rx) optical fibers. For each of multiple fiber bundles, routing respective pairs of Tx and Rx optical fibers to be coupled to respective backside optical connectors such that pair of Tx and Rx optical fibers are shuffled between the frontside optical connectors and the backside optical connectors within the optical fiber shuffle harness. Optical fiber bundles from the backside connectors coupled to optical switch modules.

Example 17. The method of example 16, wherein the switch tray, chassis, or sled has a front wall in which a third plurality of optical connectors are installed, further routing optical signals via optical fiber bundles coupled between the optical connectors in the front wall of the switch tray, chassis, or sled and the frontside optical connectors.

Example 18. The method of example 16 or 17, wherein the switch tray, chassis, or sled includes a front wall comprising the front wall of the optical fiber harness.

Example 19. The method of example 18, further comprising optically coupling first segments of Tx optical fibers to second segments of Tx optical fibers via one or more optical isolators disposed within the optical fiber shuffle harness.

Example 20. The method of example 19, further comprising using an optical isolator box having first and second pluralities of ferrule lens and an optical isolator block or plate disposed therebetween to optically couple a plurality of first segments of Tx optical fibers to second segments of Tx optical fibers.

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Italicized letters, such as ‘j’, ‘k’, ‘m’, ‘n’, etc. and bolded letters m, n, x, and y in the foregoing detailed description are used to depict an integer number, and the use of a particular letter is not limited to particular embodiments. Moreover, the same letter may be used in separate claims to represent separate integer numbers, or different letters may be used. In addition, use of a particular letter in the detailed description may or may not match the letter used in a claim that pertains to the same subject matter in the detailed description.

Various components referred to above as processes, servers, or tools described herein may be a means for performing the functions described. The operations and functions performed by various components described herein may be implemented by software running on a processing element, via embedded hardware or the like, or any combination of hardware and software. Such components may be implemented as software modules, hardware modules, special-purpose hardware (e.g., application specific hardware, ASICs, DSPs, etc.), embedded controllers, hardwired circuitry, hardware logic, etc. Software content (e.g., data, instructions, configuration information, etc.) may be provided via an article of manufacture including non-transitory computer-readable or machine-readable storage medium, which provides content that represents instructions that can be executed. The content may result in a computer performing various functions/operations described herein.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments, including what is described in the Abstract, is not intended to be exhaustive or to limit the embodiments to the precise forms disclosed. While specific embodiments of, and examples for, the teachings and principles are described herein for illustrative purposes, various equivalent modifications are possible within the scope of the claims, as those skilled in the relevant art will recognize.

These modifications can be made to the embodiments in light of the above detailed description. The terms used in the following claims should not be construed to limit the claim scope to the specific embodiments disclosed in the specification and the drawings. Rather, the scope of the claims is to be determined entirely by the following claims, which are to be construed in accordance with established doctrines of claim interpretation.

What is claimed is:

1. An apparatus, comprising:
an optical fiber shuffle harness including,
a housing having front and back walls;
a first plurality of optical fiber connectors installed in the front wall, at least a portion of which have an external port and an internal port coupled to a plurality of internal optical fibers disposed within the housing; and
a second plurality of optical fiber connectors installed in the back wall, at least a portion of which include an external port and an internal port coupled to optical fibers among the plurality of internal optical fibers,
wherein the internal optical fibers are cross-connected such that, for each of at least a portion of the first plurality of optical connectors, multiple optical fibers are connected at a first end to the optical connector and respective optical fibers among the multiple optical fibers are connected at second ends to respective optical connectors among the second plurality of optical connectors.

2. The apparatus of claim 1, wherein a first portion of the plurality of internal optical fibers are transmit (Tx) optical fibers configured for transmitting optical signals and a second portion of the plurality of internal optical fibers are receive (Rx) optical fibers configured for receiving optical signals.

3. The apparatus of claim 2, further comprising a plurality of optical isolator boxes, wherein at least a portion of the Tx optical fibers are optically coupled via an optical isolator box among the plurality of optical isolator boxes.

4. The apparatus of claim 3, wherein an optical isolator box comprises,
a first lens ferrule having a plurality of optical lenses configured at a first end to be coupled to a respective Tx optical fiber in a first bundle of Tx optical fibers and having a lens at a second end, the first lens ferrule configured in a first longitudinal direction;
a second lens ferrule oriented 180 degrees relative to first longitudinal direction and having a plurality of optical lenses configured at a first end to be coupled to a respective Tx optical fiber in a second bundle of Tx optical fibers and having a lens at a second end; and
an optical isolator block or plate, disposed between the lenses on the first and second lens ferrules.

5. The apparatus of claim 4, wherein the optical isolator includes a first end block and a second end block, each having first apertures through which a respective bundle among the first and second bundles of Tx optical fibers pass and second apertures through which a bundle of Rx optical fibers pass.

6. The apparatus of claim 1, wherein the internal optical fibers are fully cross connected such that when external optical fiber bundles are installed in respective external receptacles for each of the first plurality of optical fiber connectors and when external optical fibers bundles are installed in respective external receptacles for each of the second plurality of optical fiber connectors, each optical fiber in an external optical fiber bundles for a given external port for an optical fiber connector in the first plurality of optical fiber connector is coupled via a respective signal path to an optical fiber in a respective optical fiber bundle connected to the respective second plurality of optical fiber connectors.

7. The apparatus of claim 1, wherein the apparatus is a switch tray or sled, further comprising:
a plurality of electrical to optical (e2o) switch modules, each e2o switch module coupled to at least one optical fiber bundle coupled to a respective external receptacle of an optical fiber connector in the second plurality of optical fiber connectors.

8. The apparatus of claim 7, wherein the switch tray or sled includes a tray, chassis, or sled having a plurality of cable interfaces installed in an end of the tray, chassis, or sled, and wherein an e2o switch module includes an electrical interface via which signals from plurality of cables coupled between the electrical interface and a portion of the cable interfaces are electrically coupled.

9. The apparatus of claim 1, wherein the apparatus is a switch tray or sled, further comprising:
a plurality of optical to optical (o2o) switch modules, each o2o switch module coupled to at least one optical fiber bundle coupled to a respective external receptacle of an optical fiber connector in the second plurality of optical fiber connectors.

10. The apparatus of claim 1, wherein the apparatus is a switch tray or sled having a front wall comprising the front wall of the optical fiber shuffle harness housing.

11. A system, comprising:
a first rack, including,
a first plurality of compute trays, each including a plurality of other processing units (XPUs) and a plurality of electric cable ports;
a plurality of electrical-to-optical (e2o) switch trays, each having a plurality of electric cable ports and a plurality of optical cable ports, a plurality of e2o switch modules and an optical fiber shuffle harness; and
a plurality of electrical cables connecting electric cable ports on the compute trays to electric cable ports on the plurality of e2o switch trays;
a second rack, including,
a plurality of optical-to-optical (o2o) switch trays, each including,
a plurality of optical fiber ports installed on a frontside wall, the optical fiber ports having an internal port and an external port;
an optical fiber shuffle harness; and
a plurality of (o2o) switch modules; and
a plurality of optical cables coupled between optical cable ports on the e2o switch trays and optical cable ports on the o2o switch trays.

12. The system of claim 11, wherein an optical fiber shuffle harness comprises:
a housing having front and back walls;
a first plurality of optical fiber connectors installed in the front wall;
a second plurality of optical fiber connectors installed in the back wall; and
a plurality of optical fibers, wherein groups of optical fibers are coupled as bundles to the optical fiber connectors installed in the front wall and wherein pairs of transmit (Tx) and receive (Rx) optical fibers in a given bundle are routed to different optical fiber connectors installed in the back wall such that the routing of optical signals within the optical fiber shuffle harness are shuffled.

13. The system of claim 12, wherein at least a portion of the optical fiber shuffle harnesses include one or more optical isolator boxes configured to optically couple first and second segments of Tx optical fibers.

14. The system of claim 13, wherein an optical isolator box comprises:
a first lens ferrule having a plurality of optical lenses configured at a first end to be coupled to a respective Tx optical fiber in a first bundle of Tx optical fibers and having a lens at a second end, the first lens ferrule configured in a first longitudinal direction;
a second lens ferrule oriented 180 degrees relative to first longitudinal direction and having a plurality of optical lenses configured at a first end to be coupled to a respective Tx optical fiber in a second bundle of Tx optical fibers and having a lens at a second end; and
an optical isolator block or plate, disposed between the lenses on the first and second lens ferrules.

15. The system of claim 11, wherein each of at least one of the e2o switch trays or o2o switch trays includes a front wall that also serves as the front wall of the optical fiber shuffle harness for that e2o or o2o switch tray.

16. A method implemented in a switch tray, chassis, or sled having a plurality of switch modules and including an optical fiber shuffle harness having a plurality of frontside optical connectors installed in a front wall and a plurality of backside optical connectors installed in a back wall, the method comprising:
coupling optical fiber bundles to respective frontside optical connectors, each optical fiber bundle including at least four pairs of transmit (Tx) and receive (Rx) optical fibers;
for each of multiple fiber bundles, routing respective pairs of Tx and Rx optical fibers to be coupled to respective backside optical connectors such that pair of Tx and Rx optical fibers are shuffled between the frontside optical connectors and the backside optical connectors within the optical fiber shuffle harness; and
coupling optical fiber bundles from the backside connectors to optical switch modules.

17. The method of claim 16, wherein the switch tray, chassis, or sled has a front wall in which a third plurality of optical connectors are installed, further routing optical signals via optical fiber bundles coupled between the optical connectors in the front wall of the switch tray, chassis, or sled and the frontside optical connectors.

18. The method of claim 16, wherein the switch tray, chassis, or sled includes a front wall comprising the front wall of the optical fiber harness.

19. The method of claim 18, further comprising optically coupling first segments of Tx optical fibers to second segments of Tx optical fibers via one or more optical isolators disposed within the optical fiber shuffle harness.

20. The method of claim 19, further comprising using an optical isolator box having first and second pluralities of ferrule lens and an optical isolator block or plate disposed therebetween to optically couple a plurality of first segments of Tx optical fibers to second segments of Tx optical fibers.
